(19) United States
(12) Patent Application Publication
(10) Pub. No.: US 2020/0119041 A1
(43) Pub. Date: Apr. 16, 2020

(54) MEMORY DEVICE AND METHOD FOR FORMING THE SAME

(71) Applicant: MACRONIX INTERNATIONAL CO., LTD., Hsinchu (TW)

(72) Inventor: Guan-Ru LEE, Kaohsiung City (TW)

(21) Appl. No.: 16/161,127

(22) Filed: Oct. 16, 2018

(51) Int. Cl. H01L 27/11582; H01L 21/28; H01L 21/02; H01L 29/08; H01L 21/311; H01L 21/3065; H01L 27/11568

(52) U.S. Cl. CPC H01L 27/11582; H01L 21/28282; H01L 21/02532; H01L 29/0847; H01L 21/31116; H01L 29/167; H01L 27/11568; H01L 21/02595; H01L 21/02598; H01L 21/02579; H01L 21/3065

(57) ABSTRACT

A method for forming a three-dimensional memory device, comprising: forming a ridge-shaped stack including a plurality of conductive strips stacked on the substrate along a first direction and extending along a second direction; forming a memory layer stacked on a vertical sidewall of the ridge-shaped stack along a third direction; forming a channel layer stacked on a vertical sidewall of the memory layer along the third direction and having a narrow sidewall with a long side extending along the first direction; forming a capping layer stacked on the ridge-shaped stack in the first direction, the capping layer covering the memory layer and the channel layer; and forming a conductive connecting layer stacked on the narrow sidewall along the second direction.

### BACKGROUND OF THE INVENTION

### Field of the Invention

The invention in generally relates to a high density memory device and method for forming the same, and more particularly to a three dimensional (3D) memory device a method for forming the same.

### Description of the Related Art

The 3D memory devices, such as a 3D non-volatile memory (NVM) which has a multi-layer stack structure may possess a higher density memory and excellent electrical characteristics, e.g. reliability in data storage and high operating speed, has been provided in order to accommodate the rising demand for superior memory. Moreover, the 3D NVM is a suitable architecture for AI (Artificial Intelligence) application.

A typical method for forming a 3D memory device includes a source/drain formation. The source/drain formation may be performed by implantation through holes. However, it is challenging to evenly apply the implants through the holes having a high aspect ratio by the traditional implantation step, and the source/drain may not be properly formed.

Therefore, there is a need for providing an improved 3D memory device and the method for forming the same to obviate the drawbacks encountered from the prior art.

### SUMMARY OF THE INVENTION

The invention is directed to a memory device and a method for forming the same. The present disclosure provides a method for forming drain and source regions in the memory device in a better way, so as to provide the memory device having a good electrical property with a reduced production cost.

According to one aspect of the present disclosure, a method for forming a memory device is provided. The method for forming the memory device, comprising: forming a ridge-shaped stack including a plurality of conductive strips stacked on the substrate along a first direction and extending along a second direction; forming a memory layer stacked on a vertical sidewall of the ridge-shaped stack along a third direction; forming a channel layer stacked on a vertical sidewall of the memory layer along the third direction and having a narrow sidewall with a long side extending along the first direction; forming a capping layer stacked on the ridge-shaped stack in the first direction, the capping layer covering the memory layer and the channel layer; and forming a conductive connecting layer stacked on the narrow sidewall along the second direction.

The above and other aspects of the invention will become better understood with regard to the following detailed description of the preferred but non-limiting embodiment(s). The following description is made with reference to the accompanying drawings,

### BRIEF DESCRIPTION OF THE DRAWINGS

FIG. 1 is a prospective view illustrating the multi-layer stack according to one embodiment of the present disclosure.

FIG. 2 is a prospective view illustrating the result after the process for patterning the multi-layer stack is performed on the structure depicted in FIG. 1.

FIG. 3 is a prospective view illustrating the result after a conductive layer is formed on the structure depicted in FIG. 2.

FIG. 4 is a prospective view illustrating the result after a portion of the conductive layer is removed from the structure depicted in FIG. 3.

FIG. 5 is a prospective view illustrating the result after an insulation material layer is formed in the structure depicted in FIG. 4.

FIG. 6 is a prospective view illustrating the result after a conductive body is formed in the structure depicted in FIG. 5.

FIG. 7 is a prospective view illustrating the result after a capping layer is formed on the structure depicted in FIG. 6.

FIG. 8 is a prospective view illustrating the result after openings are formed in the structure depicted in FIG. 7.

FIG. 9A is a prospective view illustrating the result after conductive connecting layers are formed in the structure depicted in FIG. 8.

FIGS. 9B-9E are top views illustrating steps of the forming of the conductive connecting layers taken along the lines A-A′ and B-B′ depicted in FIG. 8 according to one embodiment of the present disclosure.

FIGS. 9F is a top view taken along the lines A-A′ and B-B′ depicted in FIG. 8 according to one embodiment of the present disclosure.

FIG. 9G is a top view taken along the lines C-C′ and D-D′ depicted in FIG. 9A according to one embodiment of the present disclosure.

FIG. 10 is a prospective view illustrating the result after contacts and conductive lines are formed on the structure depicted in FIG. 8.

FIGS. 11A-11D are top views illustrating a method for forming a memory device according to another embodiment of the present disclosure.

### DETAILED DESCRIPTION OF THE INVENTION

It is to be noted that the following descriptions of preferred embodiments of this disclosure are presented herein for purpose of illustration and description only. It is not intended to be exhaustive or to be limited to the precise form disclosed. Also, it is also important to point out that there may be other features, elements, steps and parameters for implementing the embodiments of the present disclosure which are not specifically illustrated. Thus, the specification and the drawings are to be regarded as an illustrative sense rather than a restrictive sense. Various modifications and similar arrangements may be provided by the persons skilled in the art within the spirit and scope of the present disclosure. In addition, the illustrations may not be necessarily be drawn to scale, and the identical elements of the embodiments are designated with the same reference numerals.

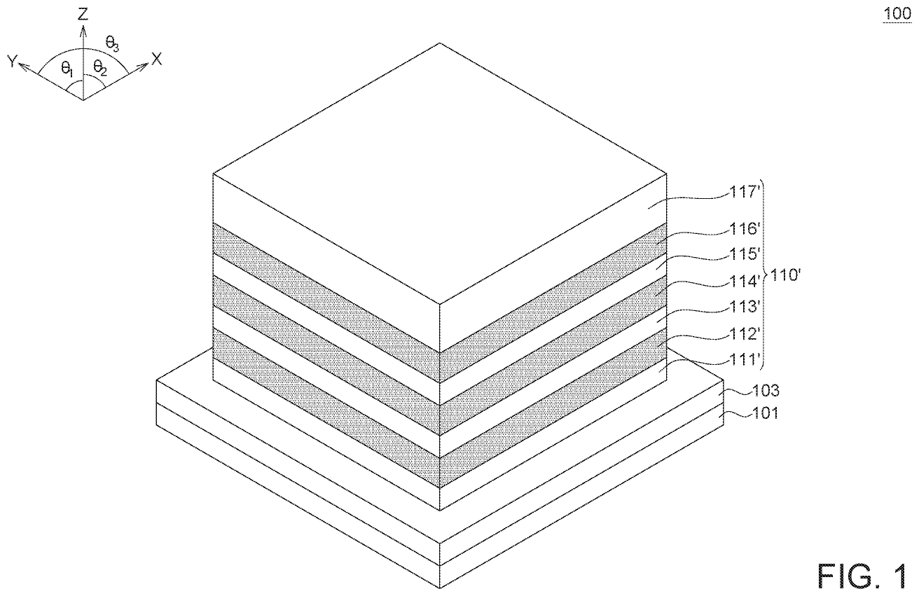

The method for fabricating a 3D memory device 100 comprises several steps as follows: Firstly, a multi-layer stack 110′ is formed on a substrate 101. FIG. 1 is a prospective view illustrating the multi-layer stack 110′ according to one embodiment of the present disclosure. In some embodiments of the present disclosure, the multi-layer stack 110′ is formed on a semiconductor substrate 101. A barrier layer 103 may be formed on the substrate 101 and disposed between the multi-layer stack 110′ and the substrate 101. The multi-layer stack 110′ comprises a plurality of insulating layers 111′, 113′, 115′, 117′, and a plurality of conductive layers 112′, 114′, 116′. In the present embodiment, the insulating layers 111′, 113′, 115′, 117′ are alternately stacked with the conductive layer 112′, 114′, 116′ on the substrate 101 along a first direction (such as the Z-orientation) as illustrated in FIG. 1. As a result, the insulating layer 111′ is disposed at the bottom of the multi-layer stack 110′, and the insulating layer 117′ is disposed at the top of the multi-layer stack 110′.

The conductive layers 112′, 114′, 116′ can be formed of a conductive semiconductor material, such as n-type poly-silicon, or n-type epitaxial single crystal silicon, doped with phosphorus or arsenic. Alternatively, the conductive layers 112′, 114′, 116′ can be formed of p-type poly-silicon, or p-type epitaxial single crystal silicon, doped with boron. Still alternatively, the conductive layers 112′, 114′, 116′ can be formed of un-doped semiconductor material, such as un-doped In the present embodiment, the conductive layers 112′, 114′, 116′ are preferably formed of un-doped poly-silicon.

The insulating layers 111′, 113′, 115′, 117′ can be formed of a dielectric material such as silicon oxide, silicon nitride, silicon oxynitride, silicate, or others. The thickness of each one of the insulating layers 111′, 113′, 115′, 117′ can be about 20 nm to 40 nm. In some embodiments of the present disclosure, the conductive layers 112′, 114′, 116′ and the insulating layers 111′, 113′, 115′, 117′ can be formed by a deposition process, for example, a low pressure chemical vapor deposition (LPCVD) process.

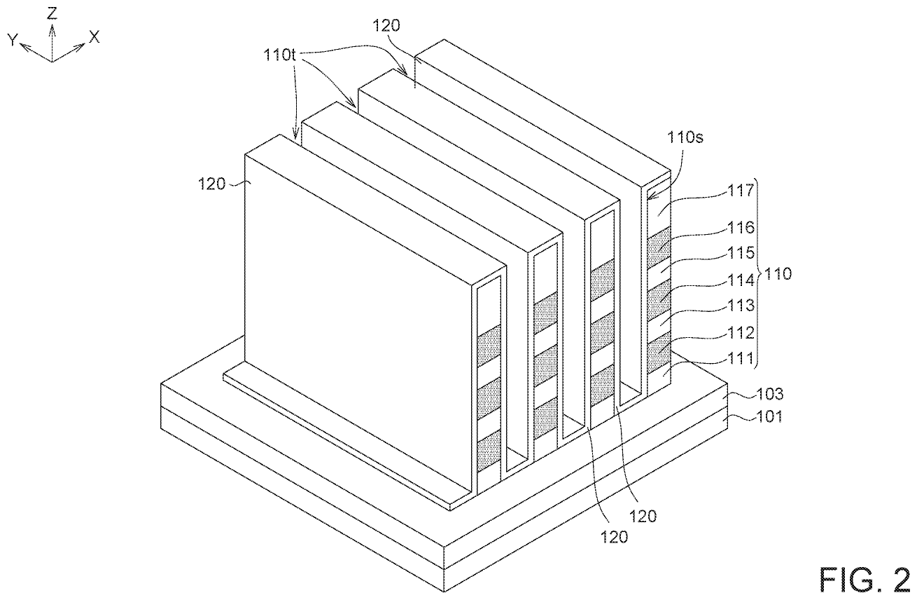

Next, the multi-layer stack 110′ is patterned to form a plurality of ridge-shaped stacks 110. FIG. 2 is a prospective view illustrating the result after the process for patterning the multi-layer stack 110′ is performed on the structure depicted in FIG. 1 and a memory material layer 120 is formed on the patterned multi-layer stack 110′. Each of the trenches 110t has a long axis extending along a second direction (such as the Y orientation) to divide the multi-layer stack 110′ into a plurality of ridge-shaped stacks 110, and expose portions of the barrier layer 103. In the present embodiment, each of the ridge-shaped stacks 110 comprises a portion of the conductive layers 112′, 114′, 116′ and insulating layers 111′, 113′, 115′, 117′ each of which is respectively shaped as a conductive stripe 112, 114, 116 and insulating strips 111, 113, 115, 117. Vertical sidewalls 110s of the ridge-shaped stacks 110 may be exposed from the trenches 110t. Thereafter, the ridge-shaped stacks 110 may be covered by the memory material layers 120 through a LPCVD process and the memory material layers 120 may be stacked on the vertical sidewalls 110s of the ridge-shaped stacks 110 along a third direction (such as X orientation).

In one embodiment, a non-straight angle θ₁ (e.g. about 90°) can be formed by the first direction (Z orientation) and the second direction (the Y orientation), a non-straight angle non-straight angle θ₂ (e.g. about 90°) can be formed by the third direction (X orientation) and the first direction (the Z orientation), a non-straight angle non-straight angle θ₃ (e.g. about 90°) can be formed by the third direction (the X orientation) and the second direction (Y orientation).

The memory material layer 120 may be formed of a composite layer (i.e., an ONO layer) including a silicon oxide layer, a silicon nitride layer, and a silicon oxide layer, by a LPCVD process. However, the structure of the memory material layer 120 is not limited to this regards. In some embodiments, the memory material layer 140 may be selected from a group consisting of an oxide-nitride-oxide-nitride-oxide (ONONO) structure, a silicon-oxide-nitride-oxide-silicon (SONOS) structure, a bandgap engineered silicon-oxide-nitride-oxide-silicon (BE-SONOS) structure, a tantalum nitride-aluminum oxide-silicon nitride-silicon oxide-silicon (TANOS) structure and a metal-high-k bandgap-engineered silicon-oxide-nitride-oxide-silicon (MA BE-SONOS) structure.

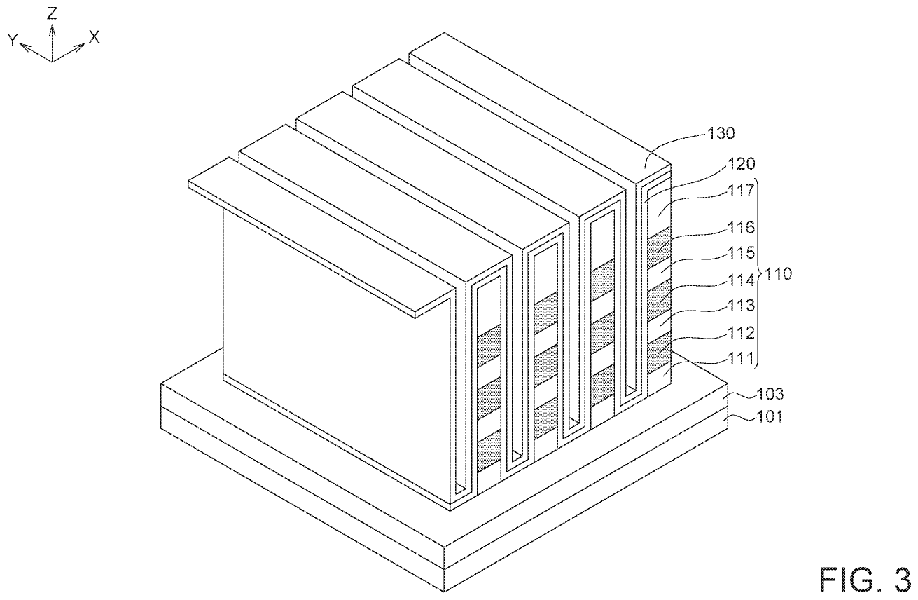

FIG. 3 is a prospective view illustrating the result after a conductive layer 130 is formed on the structure depicted in FIG. 2. In some embodiments of the present disclosure, the conductive layer 130 is formed by a LPCVD process, so as to conformally blanket over the surface of the ridge-shaped stacks 110.

The conductive layer 130 may include an electrically conductive material, such as n+-type poly-silicon (n-type epitaxial single crystal silicon) is doped with phosphorus or arsenic, p+-type poly-silicon (p-type epitaxial single crystal silicon) doped with boron or un-doped polysilicon. Alternatively, the conductive layer 130 may be formed of silicide, such as TiSi, CoSi, or SiGe, oxide semiconductor, such as InZnO or InGaZnO, metal, such as Al, Cu, W, Ti, Co, Ni, TiN, TaN, or TaAIN, or a combination of two or more of these materials.

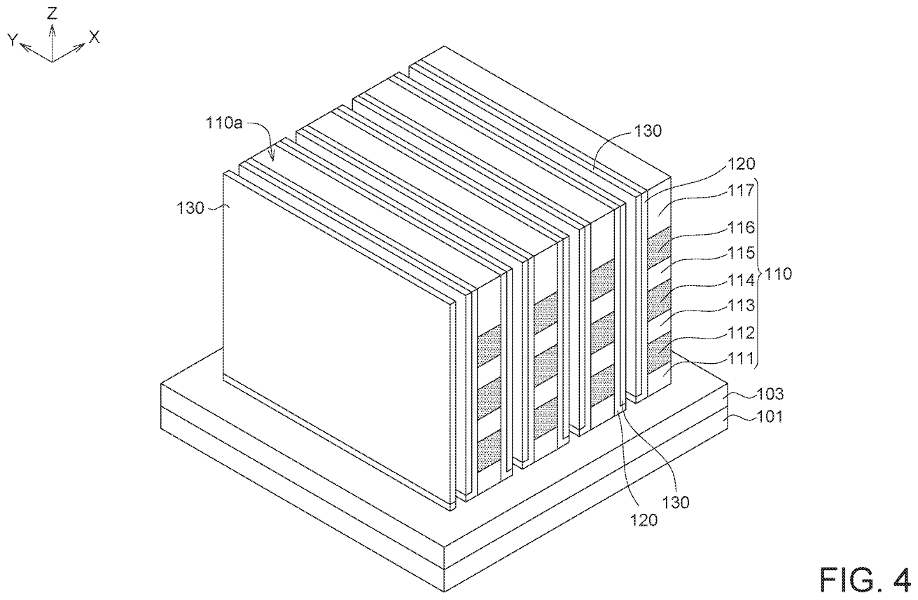

FIG. 4 is a prospective view illustrating the result after a portion of the conductive layer 130 and a portion of the memory material layer 120 are removed from the structure depicted in FIG. 3. In some embodiments, a portion of the conductive layer 130 and a portion of the memory material layer 120 are removed by an etching process.

A top portion and a bottom portion of the conductive layer 130 are removed, That is, portions of the conductive layer 130 and the memory material layer 120 covering the top surface 110a of the ridge-shaped stacks 110 and contacting or adjacent to the barrier layer 103 are partially removed, so as to expose the top surface 110a of the ridge-shaped stacks 110 and the barrier layer 103 from the conductive layer 130 and the memory material layer 120. The conductive layer 130 stacked on the memory material layer 120 in the third direction (i.e. X orientation) is remained.

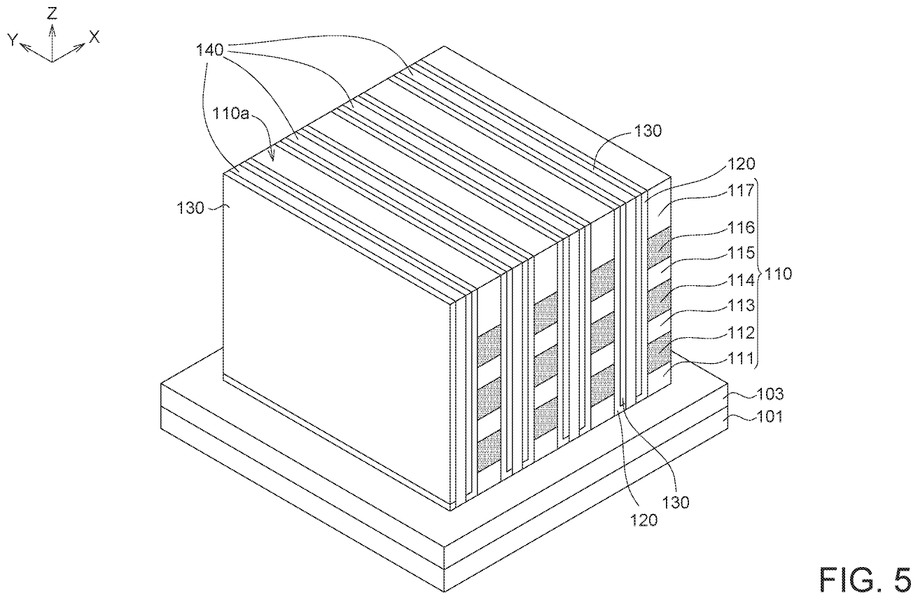

FIG. 5 is a prospective view illustrating the result after an insulation material layer 140 is formed in the structure depicted in FIG. 4. In some embodiments, insulation material layer 140 is formed by a LPCVD process.

The insulation material layer 140 may be made of an oxide material, such as a material including silicon dioxide. The insulation material layer 140 is filled in the trenches 110t and disposed between the conductive layers 130. The memory material layer 120, the conductive layer 130 and the insulation material layer 140 can be regarded as stacking on the vertical sidewall 110s of the ridge-shaped stacks 110 in sequence along a third direction (i.e. the X orientation).

FIG. 6 is a prospective view illustrating the result after a conductive body 150 is formed in the structure depicted in FIG. 5.

In the present embodiment, a top portion of insulation material layer 140 may be removed by an etching process, so as to form shallow trenches 140st to expose the insulation material layer 140. A top surface 140a of the etched insulation material layer 140 is regarded as a bottom of the shallow trench 140st. Subsequently, the conductive body 150 is formed in the shallow trench 140st and covering the top surface 140a. The top surface 140a has a vertical height from the substrate 101 smaller than that of the top surface 110a of the ridge-shaped stack 110. A top surface 150a of the conductive body 150 has a same height with the top surface 110a of the ridge-shaped stack 110 measured from the substrate 101.

The conductive body 150 may be formed of conductive semiconductor material, such as n+-type poly-silicon (n-type epitaxial single crystal silicon) doped with phosphorus or arsenic, p+-type poly-silicon (p-type epitaxial single crystal silicon) doped with boron or un-doped polysilicon. In the present embodiment, the conductive body 150 is formed of un-doped polysilicon.

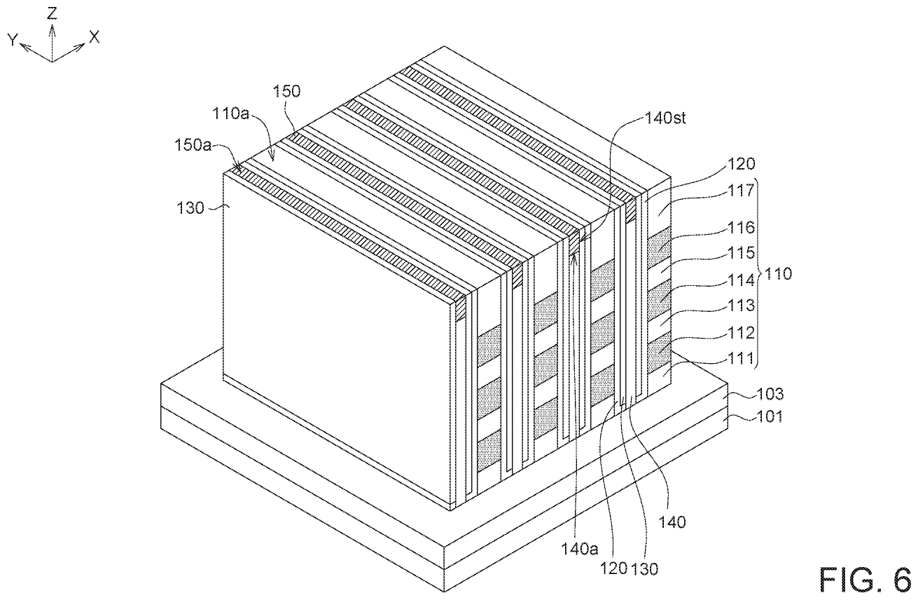

FIG. 7 is a prospective view illustrating the result after a capping layer 160 is formed on the structure depicted in FIG. 6. The capping layer 160 may be formed by a LPCVD process.

The capping layer 160 entirely covers the top surface 150a of the conductive body 150, the top surface 110a of the ridge-shaped stack 110 and the memory material layer 120. In some embodiments, the capping layer 160 may include a material of SiN, oxide, SiON, or any other material which has a high selectivity for the following chemical dry etching (ODE) process. The capping layer 160 may have a thickness in a range of 100-200 angstroms.

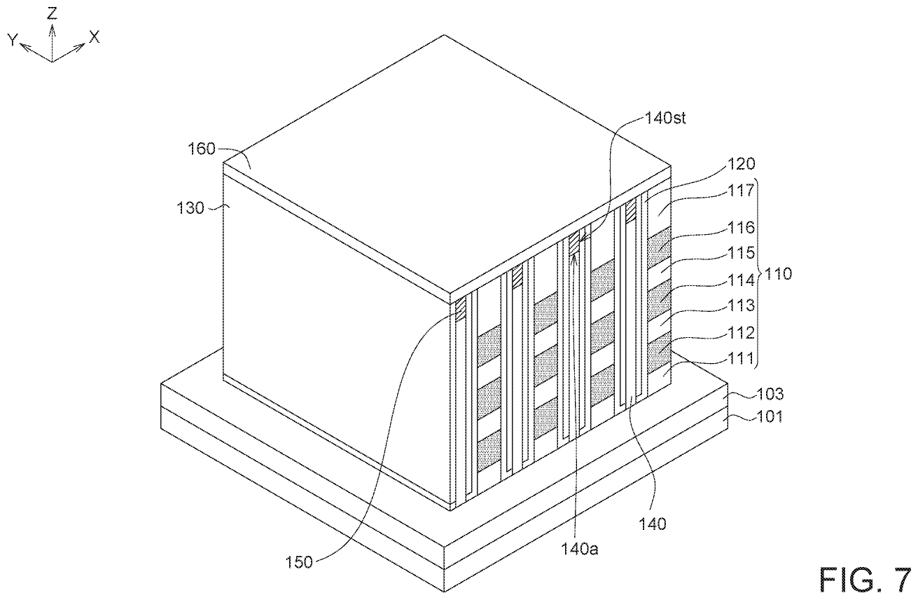

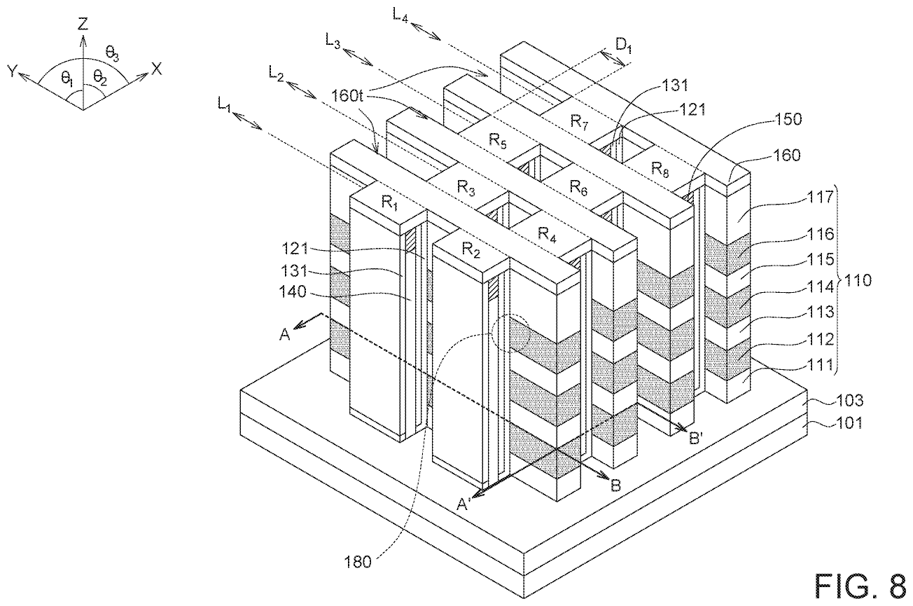

FIG. 8 is a prospective view illustrating the result after openings 160t are formed in the structure depicted in FIG. 7.

An opening etching process is performed to remove portions of the memory material layer 120, the conductive layer 130, the insulation material layer 140 and the capping layer 160, so as to form a plurality of openings 160t exposing barrier layer 103. The remained portions of the memory material layer 120, the conductive layer 130, the insulation material layer 140 and the capping layer 160 can be divided into a plurality of regions R₁-R₈ arranged in a twisted layout. In other words, regions R₁ and R₂ are disposed in a first line L₁ parallel to the second direction (Y orientation); regions R₃ and R₄ are disposed in a second line L₂ parallel to the second direction (Y orientation); regions R₅ and R₆ are disposed in a third line L₃ parallel to the second direction (Y orientation); regions R₇ and R₈ are disposed in a fourth line L₄ parallel to the second direction (Y orientation). The regions in adjacent lines are offset in a distance along the second direction (Y orientation). For example, the regions R₁ and R₃ are respectively aligned with the regions R₅ and R₇ in the second direction (Y orientation), and the regions R₁ and R₅ are respectively offset from the regions R₃ and R₇ in a distance D₁ along the second direction (Y orientation).

A memory cell 180 thus can be formed by the remained memory material layer 120 (thereinafter referred to as a memory layer 121) and the remained conductive layer 130 (thereinafter referred to as a channel layer 131) and the corresponding conductive strips 112, 114, 116 disposed on each level of the ridge-shaped stacks 110 on the intersection point thereof.

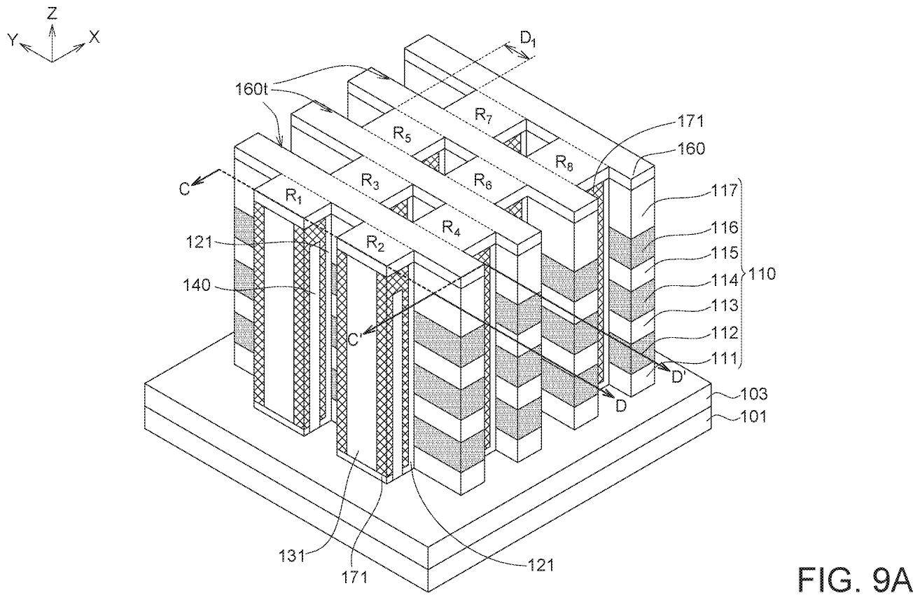

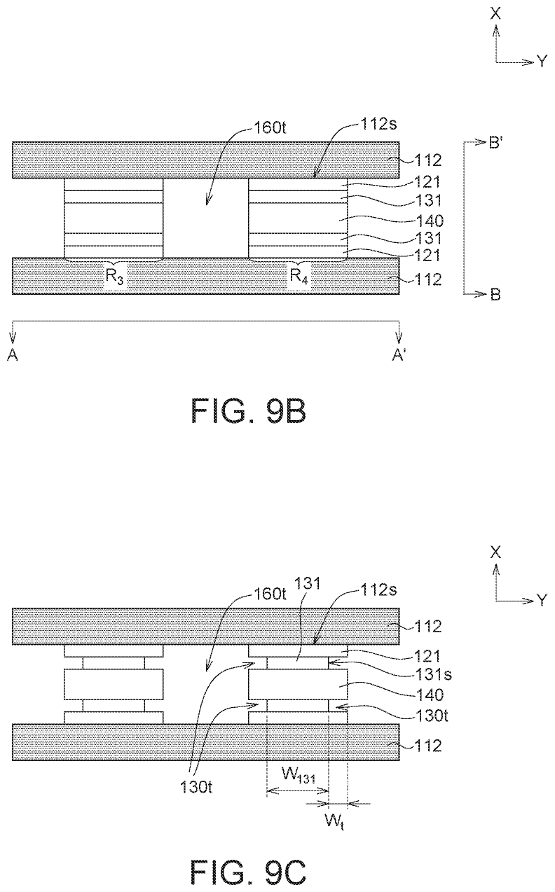

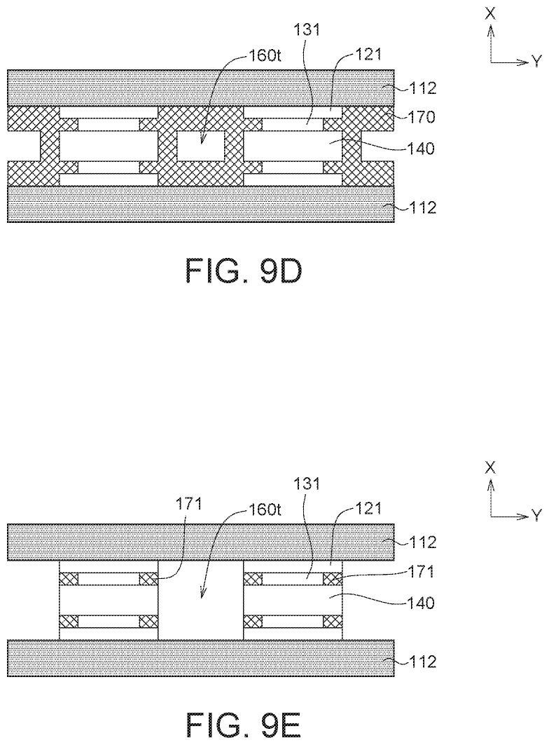

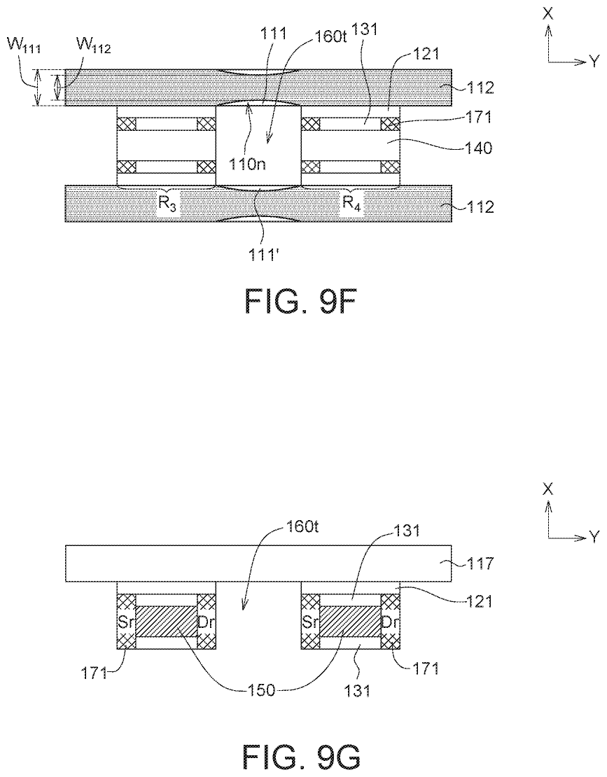

FIG. 9A is a prospective view illustrating the result after conductive connecting layers 171 are formed in the structure depicted in FIG. 8.

The conductive connecting layers 171 are stacked on the channel layer 131 and the conductive body 150 in the second direction (i.e. Y orientation). More detailed description about the forming of the conductive connecting layers 171 are described in the following paragraphs corresponding to FIGS. 9B-9F.

FIGS. 9B-9E are top views illustrating steps of the forming of the conductive connecting layers 171 taken along the lines A-A′ and B-B′ depicted in FIG. 8 according to one embodiment of the present disclosure.

Referring to FIG. 9B, after the opening etching process, the regions R₃ and R₄ separated by the opening 160t are exemplary shown. The memory layer 121, the channel layer 131 and the insulation material layer 140 are sequentially stacked on the vertical sidewall 110s of the ridge-shaped stack 110, including a vertical sidewall 112s of the conductive strip 112, along the third direction (i.e. X orientation).

Referring to FIG. 9C, a notch 130t extending along the first direction (i.e. Z orientation) is formed by removing a portion of the channel layer 131 and a narrow sidewall 131s of the channel layer 131 is exposed. The narrow sidewall 131s serves as a bottom of the notch 130t. Two sides of each channel layer 131 may be exposed, and one channel layer 131 ay correspond to two notches 130t. The notch 130t may be formed by a first chemical dry etching (CDE) process, which selectively etching the channel layer 131, such as selectively etching the material of polysilicon. The entire structure of the memory device 100 are protected by the capping layer 160 to avoid being damaged by the chemical dry etching process. In one embodiment, the cell pitch (i.e. a distance between adjacent regions, such as regions R₃ and R₄) in a second direction (i.e. Y direction) is 140 nm and the active region has a width in a second direction (i.e. Y direction) of 70 nm, the notch 130t has a width Wₜ in a second direction (i.e. Y direction) in a range of 5 nm to 20 nm, and the channel layer 131 between two adjacent notches 130t has a width W₁₃₁ in a second direction (i.e. Y orientation) larger than 30 nm.

Referring to FIG. 9D, a cleaning process is performed to the structure depicted in FIG. 9C to remove the native oxide, and then a conductive material 170 is deposited in the openings 160t and notches 130t. The cleaning process may be performed by an etchant, such as HF. The conductive material 170 is stacked on the narrow sidewall 130s of the channel layer 131 and the vertical sidewall 110s of the ridge-shaped stack 110. The entire notches 130t and a portion of the opening 160t are filled by the conductive material 170. The conductive material 170 may be formed of a conductive semiconductor material, such as heavily doped n-type poly-silicon. The conductive material 170 may have a resistance lower than that of the channel layer 131.

Referring to FIG. 9E, a second chemical dry etching process is performed to the structure depicted in FIG. 9D to remove a portion of the conductive material 170 from the openings 160t, the conductive material 170 filled in the notches 130t is remained, so as to form the conductive connecting layer 171 stacked on the narrow sidewall 131s along the second direction (as shown in FIG. 9A). An etchant of the second chemical dry etching process selectively etches the conductive material 170, e.g. polysilicon. In this way, the conductive connecting layers 171 served as a source region Sr or a drain region Dr can be formed by a self-aligned method.

Since the conductive material 170 can be directly deposited in the notches 130t, the bottom of the notches 130t in the first direction (i.e. Z orientation) can also be filled by the conductive material 170 even if the openings 160t or the notches 130t have a high aspect ratio.

FIGS. 9F is a top view taken along the lines A-A′ and B-B′ depicted in FIG. 8 according to one embodiment of the present disclosure,

Referring to FIG. 9F, recesses 110n may be formed in the conductive strips 112, 114, 116 after the second chemical dry etching process is performed. Since both of the conductive material 170 and the conductive strips 112, 114, 116 may include a similar or the same material, such as polysilicon, the second chemical dry etching process may not only remove the conductive material 170 from the opening 160t but also remove a small portion of the conductive strips 112, 114, 116 to completely isolate different cells (such as regions R₃ and R₄), and therefore the recesses 110n in the conductive strips 112, 114, 116 are produced. That is, the conductive strips 112, 114, 116 may have a first width (such as W₁₁₂) in the third direction (i.e. X orientation) corresponding to the opening 160t, the insulating strips 111, 113, 115, 117 may have a second width (such as W₁₁₁) in the third direction (i.e. X orientation) corresponding to the opening 160t, and the first width (such as W₁₁₂) is smaller than the second width (such as W₁₁₁).

FIG. 9G is a top view taken along the lines C-C′ and D-D′ depicted in FIG. 9A according to one embodiment of the present disclosure.

During the processes exemplarily shown in FIGS. 9B-9E, edge portions of the conductive body 150 may also be removed by the notches 130t, and the conductive connecting layers 171 are formed in the notches 130t to contact the conductive body 150 and the memory layer 121 after the conductive material 170 is filled in the notches 130t (as shown in FIGS. 9A and 9G). The conductive connecting layers 171 can serve as a source region Sr or a drain region Dr.

FIG. 10 is a prospective view illustrating the result after contacts 190 and conductive lines BL₁-BL₄, SL₁-SL₄ are formed on the structure depicted in FIG. 8.

The contacts 190 are formed on the conductive connecting layers 171. The capping layer 160 is penetrated by the contacts 190, and the contacts 190 are surrounded by the capping layer 160. Each of the regions R₁-R₈ may correspond to two conductive connecting layers 171 having an inverted-U shape, served as a source region Sr and a drain region Dr, respectively. The conductive lines BL₁-BL₄, SL₁-SL₄ are formed on and electrically connected to the contacts 190. The contacts 190 and the conductive lines BL₁-BL₄, SL₁-SL₄ may be formed of metal. The conductive line BL₁ can be used as a bit line to be electrically connected to the drain regions Dr of regions R₄ and R₈. The conductive line BL₂ can be used as a bit line to be electrically connected to the drain regions Dr of regions R₂ and R₆. The conductive line BL₃ can be used as a bit line to be electrically connected to the drain regions Dr of regions R₃ and R₇. The conductive line BL₄ can be used as a bit line to be electrically connected to the drain regions Dr of regions R₁ and R₅. The conductive line SL₁ can be used as a source line to be electrically connected to the source regions Sr of regions R₄ and R₃. The conductive line SL₂ can be used as a source line to be electrically connected to the source regions Sr of regions R₂ and R₆. The conductive line SL₃ can be used as a source line to be electrically connected to the source regions Sr of regions R₃ and R₇. The conductive line SL₄ can be used as a source line to be electrically connected to the source regions Sr of regions R₁ and R₅. The source lines (e.g. conductive lines SL₁-SL₄) currents may be summed together for sensing in the AI application.

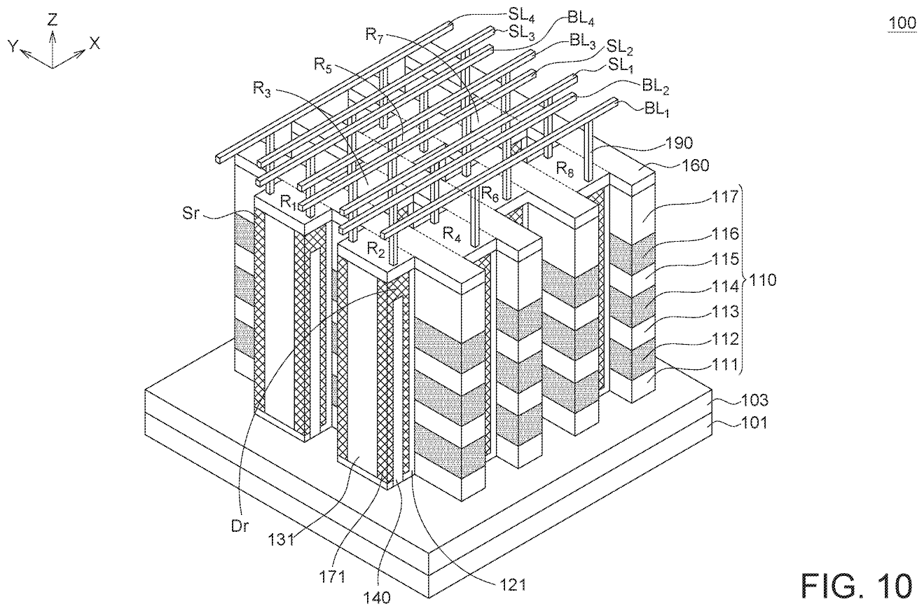

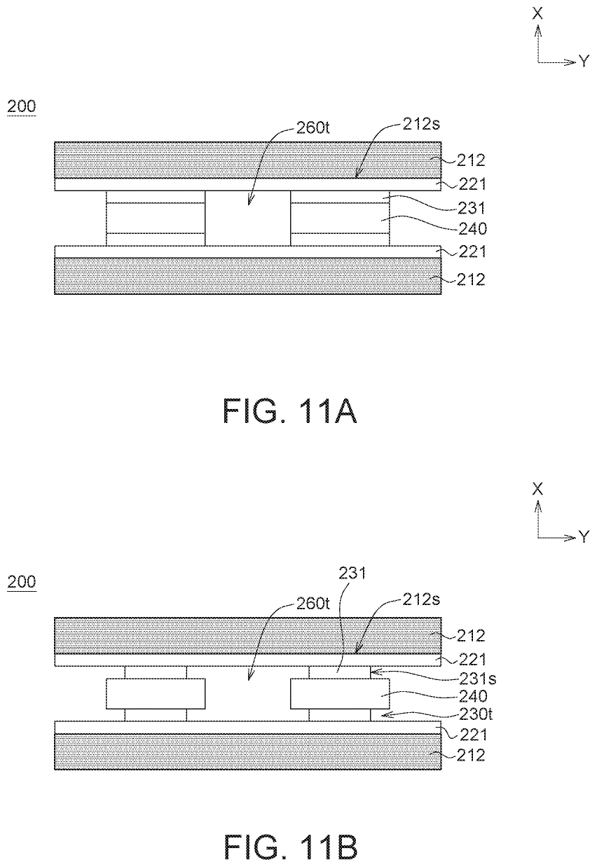

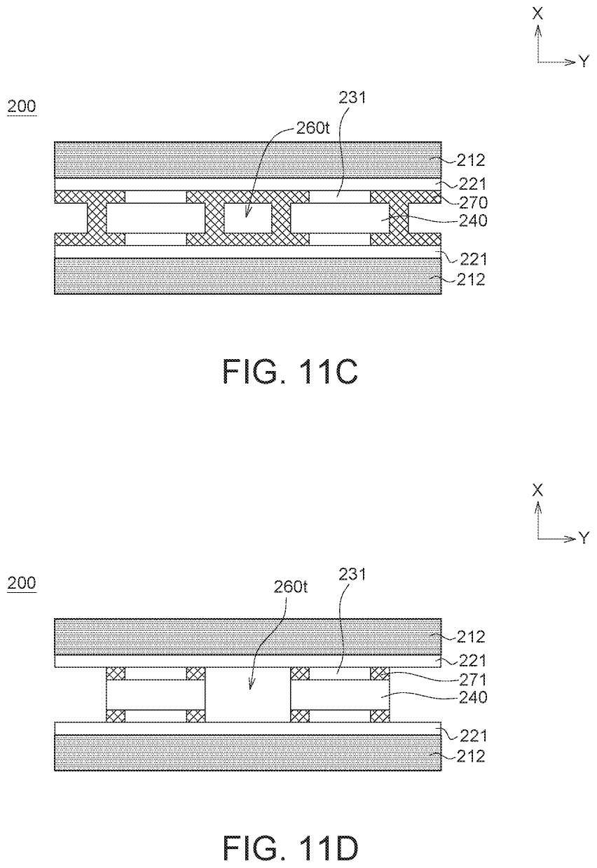

FIGS. 11A-11D are top views illustrating a method for forming a 3D memory device 200 according to another embodiment of the present disclosure.

The 3D memory device 200 is similar to the 3D memory device 100, and the difference is in that the memory layer 221 is remained in the opening 260t after the opening etching process. FIGS, 11A-11D are top views similar to FIGS. 9B-9E, respectively.

Referring to FIG. 11A, the opening etching process is performed to the structure depicted in FIG. 7, and then regions (such as regions R₃ and R₄) are separated by the openings 260t. The memory layer 221, the channel layer 231 and the insulation material layer 240 are sequentially stacked on the vertical sidewall 110s of the ridge-shaped stack 110, including a vertical sidewall 212s of the conductive strip 212, along the third direction (i.e. X orientation).The memory layer 221 is stacked on the entire vertical sidewalls 110s of the ridged-shaped stack 110, and is not removed from the openings 260t. In other words, the memory layer 221 continuously extends on the vertical sidewall 110s of the ridge-shaped stack 110 along the third direction (i.e. X orientation).

Referring to FIG. 11B, a notch 230t extending along the first direction (i.e. Z orientation) is formed by removing a portion of the channel layer 231 and a narrow sidewall 231s of the channel layer 231 is exposed. The narrow sidewall 231s serves as a bottom of the notch 230t. Two sides of each channel layer 231 may be exposed, and one channel layer 231 may correspond to two notches 230t. The notch 230t may be formed by a first chemical dry etching (CDE) process, which selectively etching the channel layer 231, such as selectively etching the material of polysilicon.

Referring to FIG. 11C, a cleaning process is performed to the structure depicted in FIG. 11B to remove the native oxide, and then a conductive material 270 is deposited in the openings 260t and notches 230t. The cleaning process may be performed by an etchant, such as HF. The conductive material 270 is stacked on the narrow sidewall 230s of the channel layer 231 and the vertical sidewall 110s of the ridge-shaped stack 110. The entire notches 230t and a portion of the opening 260t are filled by the conductive material 270. The conductive material 270 may be formed of a conductive semiconductor material, such as heavily doped n-type poly-silicon. The conductive material 270 may have a resistance lower than that of the channel layer 231.

Referring to FIG. 11D, a second chemical dry etching process is performed to the structure depicted in FIG. 11C to remove a portion of the conductive material 270 from the openings 260t, the conductive material 270 filled in the notches 230t is remained, so as to form the conductive connecting structure 271 stacked on the narrow sidewall 231s along the second direction. An etchant of the second chemical dry etching process selectively etches the conductive material 270, e.g. polysilicon. In this way, the conductive connecting layers 271 served as a source region Sr or a drain region Dr can be formed by a self-aligned method. Since the memory layers 221 are remained during the second chemical dry etching process, the conductive strips 112, 114, 116 can be protected by the memory layers 221, the etchant may have less effect to the conductive strips, and there may be no recess in the conductive strips caused by over etching.

In a first comparative example, source and drain regions are formed by implantation, but the implants may not be able to reach a bottom of the opening having a high aspect ratio. In a second comparative example, source and drain regions are formed by plasma doping without a capping layer stacked on the entire structure. The dopants may be applied to the top conductive body (or plug), and a current path may be generated between the source and drain regions.

The present disclosure discloses a 3D memory device including a capping layer covering the ridge-shaped stack and conductive body, the whole structure can be well protected by the capping layer during the following process, such as the chemical dry etching process, and the 3D memory device of the present disclosure may not be easily damaged and have a better performance. Further, the present disclosure can provide a method to form the source and drain regions of the 3D memory device by depositing the conductive connecting structure stacked on the sidewall of the channel, but not formed by implantation nor the plasma doping method. Therefore, in comparison with the first and second comparative examples, the present disclosure can provide a method to form the source and drain regions in a better way, to make sure that the source and drain regions can be properly formed even if the opening has a high aspect ratio, some elements in the memory device, such as the conductive strips and the conductive body, may not be affected by the implants and the dopants, and the current leakage may not be easily produced. As such, the 3D memory device of the present disclosure has a good electrical property and the method for forming the source and drain regions can be simpler and the production cost can also be reduced.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A method for forming a three dimensional (3D) memory device, comprising:
forming a ridge-shaped stack including a plurality of conductive strips stacked on a substrate along a first direction and extending along a second direction;
forming a memory layer stacked on a vertical sidewall of the ridge-shaped stack along a third direction;
forming a channel layer stacked on a sidewall of the memory layer along the third direction and having a narrow sidewall with a long side extending along the first direction;
forming a capping layer stacked on the ridge-shaped stack in the first direction, the capping layer covering the memory layer and the channel layer; and
forming a conductive connecting layer stacked on the narrow sidewall along the second direction.

2. The method according to claim 1, wherein the step for forming the ridge-shaped stack comprises:
forming a multi-layer stack on the substrate; and
patterning the multi-layer stack to form a plurality of trenches extending along the first direction and the second direction.

3. The method according to claim 1, wherein the step for forming the channel layer comprises:
performing a deposition process in the trenches to form a conductive layer stacked on the memory layer, the substrate and a top surface of the ridge-shaped stack; and
removing a portion of the conductive layer, prior to the forming of the capping layer.

4. The method according to claim 3, further comprising steps of forming an insulation material layer stacked on the conductive layer along the third direction.

5. The method according to claim 4, further comprising steps of forming a conductive body stacked on the insulation material layer in the first direction by filling a first conductive material into a shallow trench in the insulation material layer.

6. The method according to claim 5, further comprising performing an opening etching process to remove portions of the memory layer, the conductive layer and the insulation material layer, after the forming of the capping layer, so as to form at least one opening.

7. The method according to claim 6, wherein the capping layer covering the conductive body before performing the opening etching process.

8. The method according to claim 7, wherein the step of forming the conductive connecting layer comprises:
forming a notch extending along the first direction by removing a portion of the channel layer, and the narrow sidewall serves as a bottom of the notch;
depositing a second conductive material into the opening and the notch; and
removing the second conductive material from the opening and remaining the second conductive material in the notch,
wherein the conductive connecting layer serves as a source region or a drain region.

9. The method according to claim 8, wherein the notch is formed by a first chemical dry etching process, the removing of the second conductive material from the opening is performed by a second chemical dry etching process, and a cleaning process is performed before the steps of depositing the second conductive material into the opening and the notch.

10. The method according to claim 8, wherein an edge portion of the conductive body is removed by the notch, and the conductive connecting layer contacts the conductive body.

11. The method according to claim 8, wherein the conductive strips have a recess corresponding to the opening after the forming of the conductive connecting layer.

12. The method according to claim 8, wherein the ridge-shaped stack further including a plurality of insulating strips alternatively stacked with the conductive strips along the first direction, the conductive strips have a first width in the third direction corresponding to the opening, the insulating strips have a second width in the third direction corresponding to the opening, the first width is smaller than the second width.

13. The method according to claim 8, wherein the notch has a width in the second direction in a range of 5 nm to 20 nm.

14. The method according to claim 8, further comprising:
forming a contact on the conductive connecting layer, wherein the contact is surrounded by the capping layer; and
forming a conductive line electrically connected to the contact.

15. The method according to claim 5, further comprising performing an opening etching process to remove portions of the channel layer and the insulation material layer, so as to form at least one opening, after the forming of the capping layer, wherein the memory layer is remained in the opening.

16. A three dimensional (3D) memory device, comprising:
a ridge-shaped stack including a plurality of conductive strips stacked on a substrate along a first direction and extending along a second direction;
a memory layer stacked on a vertical sidewall of the ridge-shaped stack along a third direction;
a channel layer stacked on a sidewall of the memory layer along the third direction and having a narrow sidewall with a long side extending along the first direction;
a capping layer stacked on the ridge-shaped stack in the first direction, the capping layer covering the memory layer and the channel layer; and
a conductive connecting layer stacked on the narrow sidewall along the second direction.

17. The 3D memory device according to claim 16, further comprising:
an insulation material layer stacked on the channel layer along the third direction; and
a conductive body stacked on the insulation material layer in the first direction; wherein the capping layer covering the conductive body.

18. The 3D memory device according to claim 16, wherein the ridge-shaped stack further including a plurality of insulating strips alternatively stacked with the conductive strips along the first direction, the conductive strips have a first width in the third direction corresponding to an opening, the insulating strips have a second width in the third direction corresponding to the opening, the first width is smaller than the second width, wherein the opening penetrating portions of the memory layer, the channel layer, the insulation material layer, the conductive body and the capping layer.

19. The 3D memory device according to claim 16, further comprising:
a contact disposed on the conductive connecting layer, wherein the contact is surrounded by the capping layer; and
a conductive line electrically connected to the contact.

20. The 3D memory device according to claim 16, wherein the memory layer continuously extends on the vertical sidewall of the ridge-shaped stack along the second direction.
